(19) United States
(12) Patent Application Publication
(10) Pub. No.: US 2009/0305617 A1
(43) Pub. Date: Dec. 10, 2009

(54) Support plate, carrier device, releasing device, and releasing method

(75) Inventors: Akihiro Nakamura, Kanagawa (JP); Atsushi Miyanari, Kanagawa (JP); Yoshihiro Inao, Kanagawa (JP)

Correspondence Address: SCHWEGMAN, LUNDBERG & WOESSNER, P.A., P.O. BOX 2938, MINNEAPOLIS, MN, 55402, US

(73) Assignee: Tokyo Ohka Kogyo Co., Ltd, Kanagawa (JP)

(21) Appl. No.: 12/309,287

(22) PCT Filed: Apr. 17, 2007
(86) PCT No.: PCT/JP2007/000416

§ 371 Date: Feb. 20, 2009

(30) Foreign Application Priority Data
Jul. 14, 2006 (JP) 2006-194523

(51) Int. Cl. H01L 21/683; H01L 21/02; B25B 11/00; B29C 43/50

(52) U.S. Cl. 451/364; 451/388; 269/21; 264/570

(57) ABSTRACT

A support plate for supporting a wafer includes a plurality of through holes piercing the support plate in the thickness direction, and a belt-shaped or island-like flat portion on which the plurality of through holes are not formed.

### TECHNICAL FIELD

The present invention relates to a support plate for supporting a semiconductor wafer (referred to as a wafer hereinafter) used for manufacturing semiconductor chips, and to a carrier device, a releasing device, and a releasing method.

### BACKGROUND ART

Semiconductor chips used in portable electronic devices such as IC cards, mobile phones, digital cameras, etc. are manufactured by dividing a wafer into rectangular or square chips. Wafers are made by forming a circuit pattern on, for example, silicon.

In a process of manufacturing wafers, a circuit pattern is formed on a wafer, and thereafter a support plate is adhered to the circuit-formation surface of the wafer by means of bonding or the like. Next, the bottom surface (the surface opposite to the circuit-formation surface) of the wafer is thinned by grinding, polishing, etc. After the wafer has been thinned to a desired thickness, the support plate and the wafer are released from each other.

There is a method in which a wafer is suctioned and held by vacuum pressure so as to release the wafer and the support plate from each other (e.g., Patent Document 1). The releasing device disclosed in Patent Document 1 suctions and holds the bottom surface, which is opposite to the surface contacting a support plate, and releases the wafer and the support plate from each other. This configuration reduces the stress applied to wafers in releasing steps because a force is evenly applied to the bottom surface of a wafer when suctioning the wafer to be released. However, as wafers have become thinner in recent years, it has become difficult for this device to suction and hold wafers without applying stress to the wafers.

For adhering a wafer to a support plate, an adhesive agent is commonly used. When a wafer and a support plate adhered to each other using an adhesive agent are to be released from each other, a method in which a release agent for reducing the bonding power is injected into the adhesive portion between them is commonly used. Also, support plates with a plurality of through holes are widely used in order to effectively inject such release agents into adhesive portions.

For releasing support plates with a plurality of through holes from wafers, a method in which a support plate is released by gripping peripheral portions of the support plate after the injection of a release agent is known (e.g., Patent Document 2).

When the bottom surface of a wafer is suctioned and held in order to release the wafer from a support plate as disclosed in Patent Document 1, stress applied to the wafer can be reduced. However, wafers are thinned to between several tens of micrometers and several hundred micrometers as described above, and it is impossible to prevent stress from being applied to a wafer when the wafer is pulled upon to be released from a support plate.

In view of this situation, stress may be reduced by pulling on a support plate to release the support plate from a wafer. However, when it is attempted to suction and hold the bottom surface (surface opposite to the surface contacting the wafer) of the support plate, through holes in the support plate make it impossible to pull on the support plate to release it from the wafer. Therefore, when a support plate with through holes is used, side portions of the support plate are gripped in order to release the support plate and a wafer as disclosed in Patent Document 2. When side portions of a support plate are gripped, it is impossible to release the support plate and the wafer from each other with a force evenly applied to the bottom surface of the support plate, and stress is applied to the wafer.

### Patent Document 1:

### Japanese Patent Application Publication No. 2002-100595 (Abstract and FIG. 4)

### Patent Document 2:

### Japanese Patent Application Publication No. 2004-296935 (FIG. 1(e))

### DISCLOSURE OF THE INVENTION

It is an object of the present invention to provide a support plate, a carrier device, a releasing device, and a releasing method by which stress applied to a wafer when the wafer and a support plate with through holes are released from each other can be reduced.

In order to achieve the above object, the support plate according to the present invention is a support plate for supporting a wafer, including: a plurality of through holes piercing the support plate in a thickness direction; and a belt-shaped or island-like flat portion on which the plurality of through holes are not formed.

According to the configuration of the above support plate, it is possible to release a support plate with a plurality of through holes and a wafer from each other by pulling on the bottom surface (the surface opposite to the supporting surface facing the wafer) of the support plate by, for example, the suctioning and holding of a flat portion on the support plate.

Desirably, the above support plate will be greater than the wafer in diameter, and will further be provided with an outer peripheral flat portion along the periphery of the support plate.

According to this configuration, it is possible to release a support plate and a wafer from each other by pulling on the bottom surface of the support plate at the flat portion that is independent of the outer peripheral flat portion not facing the wafer when the wafer is adhered to the support plate.

Desirably, the flat portion is belt-shaped and circular around a central portion of the support plate.

According to the above configuration, θ alignment (rotary alignment) does not have to be performed between a support plate and a wafer when they are released from each other by utilizing a flat portion.

Desirably, the support plate has a plurality of the flat portions.

According to the above configuration, a support plate and a wafer can be released from each other through the plurality of flat portions, and thereby it is possible to release them from each other by pulling on the bottom surface of the support plate with an even force.

Desirably, the flat portion is belt-shaped and is between 0.3 mm and 2.0 mm in width.

According to the above configuration, it is possible to effectively inject a release agent via through holes while securing a width of the flat portion in order to allow holding by suction, etc.

Desirably, the flat portion is belt-shaped and has a width at least 1.2 times a value obtained by subtracting a diameter of the through hole from a pitch of the through holes.

According to the above configuration as well, it is possible to effectively inject a release agent via through holes while securing a width of the flat portion in order to allow the holding by suction, etc.

Desirably, the flat portion is belt-shaped, and has a width greater than a diameter of the through hole.

According to the above configuration, it is possible to effectively secure a width of the flat portion for holding by suction, etc.

Desirably, the through hole is between 0.3 mm and 0.5 mm in diameter and between 0.5 mm and 1.0 mm in pitch.

According to the above configuration, a release agent can easily be guided to an adhesive portion between the support plate and the wafer via the through holes, and the support plate can be pulled upon to be released effectively from the wafer by utilizing the flat portion.

In order to achieve the above object, the carrier device according to the present invention is a carrier device for carrying a support plate having one of the above configurations, and this device includes holding means suctioning and holding the flat portion.

Desirably, the holding means has a suctioning groove corresponding to the flat portion, and suctions and holds the support plate via the suctioning groove.

In order to achieve the above object, the releasing device according to the present invention is a releasing device for releasing a support plate and a wafer adhered to each other, including: a carrier device having one of the above configurations, and release agent supply means for supplying a release agent.

In order to achieve the above object, the releasing method according to the present invention is a method of releasing the support plate having one of the above configurations and a wafer held on the support plate via an adhesive portion, and this method includes: making a release agent reach the adhesive portion via the through holes in order to make the release agent dissolve the adhesive portion; and releasing the support plate while suctioning and holding the flat portion.

According to the present invention, it is possible to release a support plate with a plurality of through holes and a wafer from each other by pulling on the bottom surface (surface opposite to the supporting surface facing the wafer) of the support plate via suction, etc. of the flat portion on the support plate. Thereby, stress applied to a wafer when a support plate with a plurality of through holes and the wafer are released from each other can be suppressed.

### BRIEF DESCRIPTION OF THE DRAWINGS

FIG. 1 is a plan view showing a support plate according to an embodiment of the present invention;

FIG. 2 is an enlarged view showing portion A in FIG. 1;

FIG. 3 is a plan view showing a releasing device according to an embodiment of the present invention;

FIG. 4A is the first cross-sectional view schematically showing a configuration of the main section of the releasing device shown in FIG. 3;

FIG. 4B is the second cross-sectional view schematically showing a configuration of the main section of the releasing device shown in FIG. 3;

FIG. 5 is a plan view showing a support plate according to another embodiment of the present invention;

FIG. 6 is a plan view showing a support plate according to the first of the other embodiments;

FIG. 7 is a plan view showing a support plate according to the second of the other embodiments; and

FIG. 8 is a plan view showing a support plate according to the third of the other embodiments.

### BEST MODES FOR CARRYING OUT THE INVENTION

Hereinafter, a support plate, a carrier device, a releasing device, and a releasing method according to the present invention will be explained by referring to the drawings.

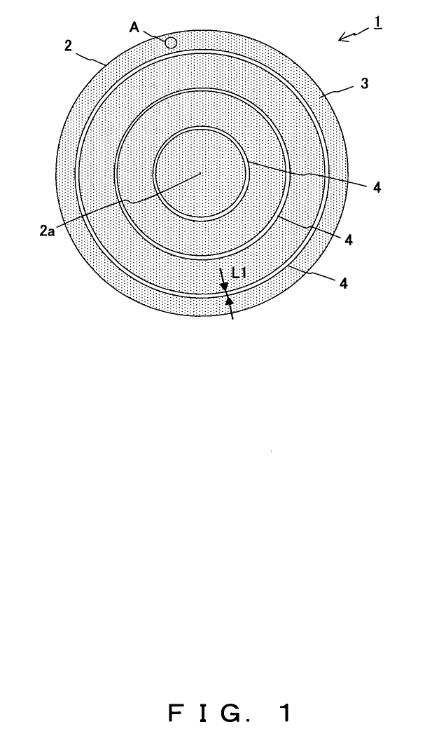

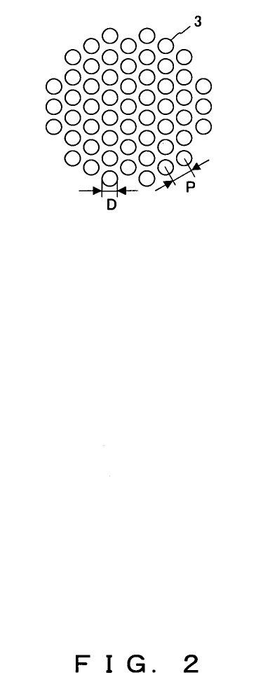

FIG. 1 is a plan view showing a support plate according to an embodiment. FIG. 2 is an enlarged view showing portion A in FIG. 1.

A support plate 1 shown in FIG. 1 supports a wafer to be thinned through, for example, a grinding process. The support plate 1 supports, via a bonding portion made of an adhesive agent, tape, etc., a wafer on its supporting surface (not shown in FIG. 1) disposed on the surface opposite to a bottom surface 2 shown in FIG. 1.

A plurality of through holes 3 (FIG. 2) are formed through the support plate 1. The through holes 3 pierce the support plate 1 from the supporting surface to the bottom surface 2 (in the thickness direction). Three belt-shaped flat portions 4 on which the through holes 3 are not formed are formed on the bottom surface 2. The respective flat portions 4 are formed in such a manner that they form concentric circles around a central portion (central point) 2a of the bottom surface 2 in the present example.

It is desirable that the width L1 of each of the flat portions 4 be between 0.3 mm and 2.0 mm. It is also desirable that the width L1 be at least 1.2 times a value obtained by subtracting a diameter D from a pitch P of the through holes 3 shown in FIG. 2.

It is also desirable that the width L1 of each flat portion 4 be greater than the diameter D of the through hole 3. The diameter D of the through hole 3 is desirably between 0.3 mm and 0.5 mm, and the pitch P is desirably between 0.5 mm and 1.0 mm.

Desirably, the pitches P and diameters D of the through holes 3 are respectively constant on the bottom surface 2. However, not all of them are always constant. Accordingly, it is desirable that the width L1 of each flat portion 4 be set on the basis of the values of the pitch P and diameter D or the values that are used most commonly as the pitches P and diameters D.

However, as the above values of the width L1 of each flat portion 4 and the pitches P and diameters D of the through holes 3 are only preferable examples, they can be set appropriately on the basis of the size of the support plate 1 or the wafer, the properties of a release agent supplied via the through holes 3, the material of an adhesive portion between the support plate 1 and the wafer, the size of a releasing device, etc. The releasing device will be explained later.

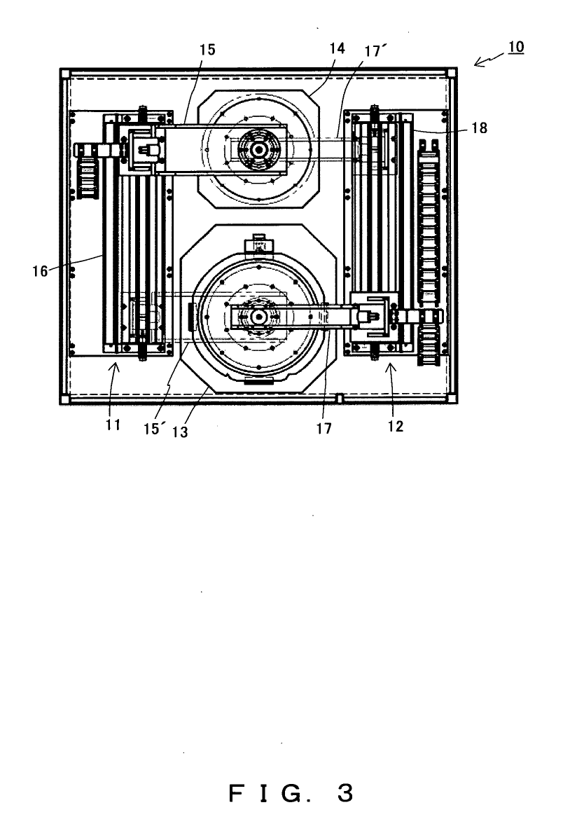

FIG. 3 is a plan view showing the releasing device according to an embodiment.

In FIG. 3, a releasing device 10 includes a carrier device 11 for carrying the support plate 1 (shown in FIG. 1), release agent supply means 12, and other units. The release agent supply means 12 supplies a release agent. The carrier device 11 and the release agent supply means 12 are arranged so that they face each other with an operation table 13 and a storage table 14 between them.

The carrier device 11 includes holding means 15 for suctioning and holding the flat portions 4 on the support plate 1 shown in FIG. 1, moving means 16 for moving the holding means 15 in the horizontal and vertical directions, and other units.

The holding means 15 has suctioning grooves corresponding to the flat portions on the support plate 1 in order to suction the support plate 1 through these grooves.

The moving means 16 is driven by driving means (not shown) to horizontally move the holding means 15 between the operation table 13 and the storage table 14 (the holding means 15 on the operation table 13 is represented by a narrow two-dot chain line 15′).

The moving means 16 moves the holding means 15 in the vertical direction between the position at which the holding means 15 contacts the support plate 1 adhered to the wafer on the operation table 13 and the retracting position.

The release agent supply means 12 has a supply unit 17 and moving means 18 and other units. The supply unit 17 supplies a release agent. The moving means 18 moves the supply unit 17 in the horizontal and vertical directions.

A release agent supplied by the supply unit 17 reduces the bonding power of an adhesive portion between the wafer and the support plate 1 shown in FIG. 1. More detailed explanation will be later given to the supply unit 17.

Similarly to the moving means 16 for moving the carrier device 11, the moving means 18 is driven by driving means (not shown) to horizontally move the supply unit 17 between the operation table 13 and the storage table 14 (the supply unit 17 on the storage table 14 is represented by a narrow two-dot chain line 17′). The moving means 18 moves the supply unit 17 in the vertical direction between the position at which the supply unit 17 supplies a release agent to the support plate 1 adhered to a wafer on the operation table 13 and the retracting position.

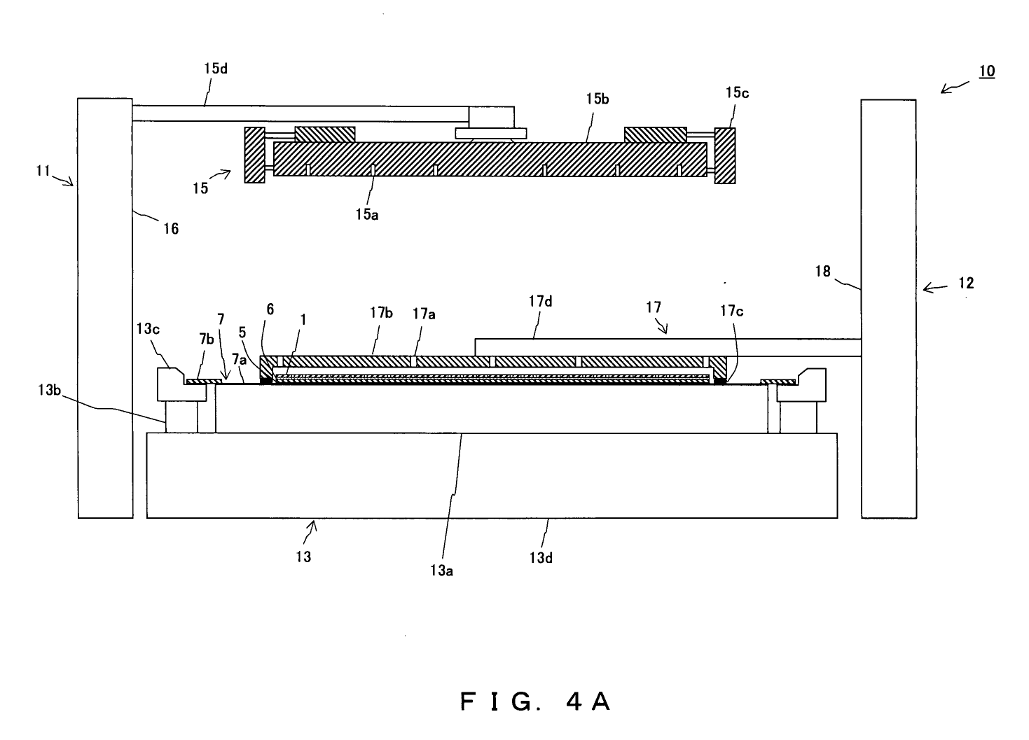

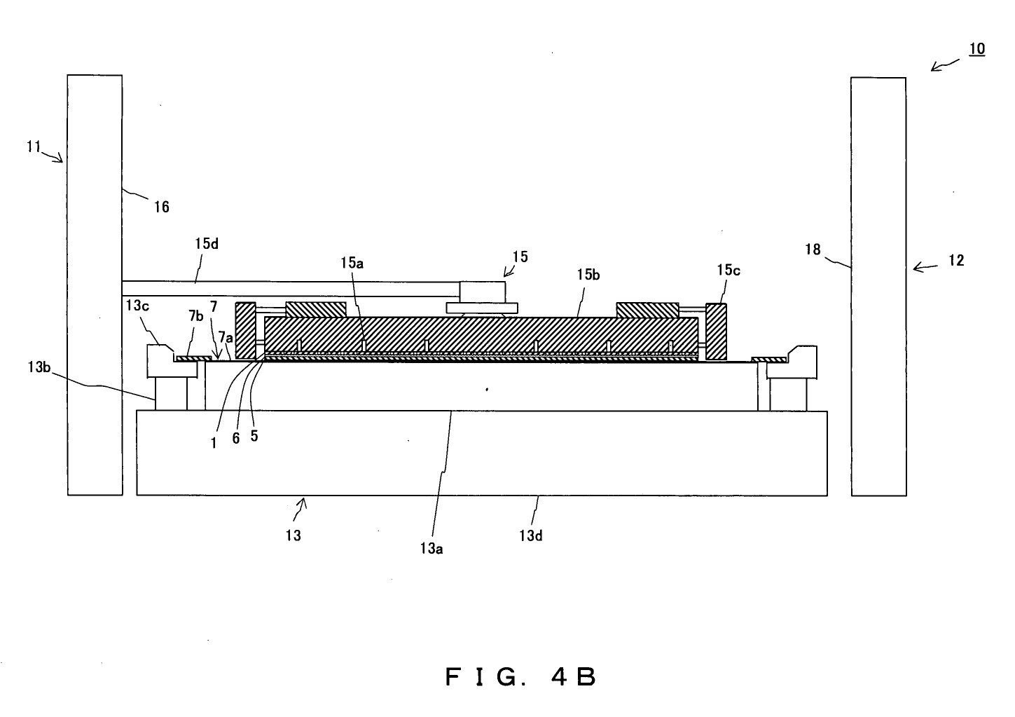

FIGS. 4A and 4B are cross-sectional views schematically showing a configuration of the main section of the above releasing device.

In FIG. 4A, the support plate 1 is adhered to a wafer 5 via an adhesive portion 6. The wafer 5 and the support plate 1 are set on the operation table 13 with the surface of the wafer 5 opposite to the surface contacting an adhesive portion 6 being adhered to dicing tape 7a of a dicing frame 7. The dicing frame 7 is adhered to the surface of the thinned wafer opposite to the surface supported on the support plate 1.

The dicing frame 7 includes the dicing tape 7a adhered to the wafer 5, and a hold portion 7b that is disposed at the periphery of the dicing tape 7a and is held when the dicing frame 7 is moved, etc. At minimum, when the support plate and the wafer are released from each other, the dicing tape 7a of the dicing frame 7 is held by a suction plate 13a of the operation table 13 by, for example, vacuum suction.

In the present embodiment, the hold portion 7b of the dicing frame 7 is held by a frame guide 13c on a lift pin 13b that can move up and down. The lift pin 13b and the suction plate 13a are provided to a base unit 13d.

In FIG. 4A, the support plate 1 and the wafer 5 set on the suction plate 13a are covered with a supply chamber 17b in which supply holes 17a are formed. The supply chamber 17b is a unit of the supply unit 17 of the release agent supply means 12. Through these supply holes 17a, a release agent is injected to be supplied to the adhesive portion 6 via the through holes in the support plate 1. At the bottom end of the supply chamber 17b, an O-ring 17c is set in order to prevent the leakage of the release agent.

The release agent reduces the bonding power of the adhesive portion 6 during a prescribed time, and thereafter is suctioned to be discharged via the supply holes 17a in the supply chamber 17b. For this suction, it is desirable to supply nitrogen gas or the like to the supply chamber 17b while suctioning the release agent.

After suctioning the release agent, the supply unit 17 is moved, by the moving means 18 connected to the supply unit 17 via an arm 17d, to the storage table 14 shown in FIG. 3 in such a manner that this movement does not prevent the suctioning of the support plate 1 by the holding means 15 of the carrier device 11. Desirably, the storage table 14 has a pan for receiving the release agent dropping from the supply chamber 17b.

As shown in FIG. 4B (in which the supply unit 17 is not shown), the moving means 16 moves holding means 15 of the carrier device 11 to the position at which the holding means 15 contacts the support plate 1 after the supply unit 17 has been moved to the storage table 14 shown in FIG. 3.

The holding means 15 includes a suction pad 15b, an aligner 15c, an arm 15d, and other units. On the suction pad 15b, suction grooves 15a corresponding to the flat portions 4 on the support plate 1 shown in FIG. 1 are formed. The aligner 15c is disposed at the periphery of the suction pad 15b, and performs alignment of the suction pad 15b in the horizontal direction. The arm 15d connects the suction pad 15b and the moving means 16 to each other.

When the suction pad 15b has contacted the support plate 1, the holding means 15 suctions and holds the support plate 1 via the suction grooves 15a with the suction plate 13a suctioning and holding the side of the dicing tape 7a. Upon this suction, the support plate 1 is suctioned through electrostatic adsorption, etc. so that the wafer 5 and the dicing plate 7 are not released from each other and so that the wafer 5 and the support plate 1 are released from each other. Additionally, when nitrogen gas is supplied from the suction pad 15b to the support plate 1, the surface tension between the support plate 1 and the wafer 5 is reduced, resulting in easier suction.

When the support plate 1 has been suctioned and held by the suction pad 15b, the moving means 16 moves the holding means 15 to the storage table 14 shown in FIG. 3. Thereafter, the released support plate 1 is stored in a storage stage (not shown) of the storage table 14.

The wafer 5 from which the support plate 1 has been released is carried to a different device, and the dicing frame 7 is released from the wafer 5. Thereafter, the wafer 5 is divided into semiconductor chips in desired sizes for practical use.

In the present embodiment, an explanation has been given for a case where suction pad 15b suctions and holds the support plate 1. However, the support plate 1 and the wafer 5 may be released from each other through the adhesion, the engagement, etc. on the flat portions 4 on the support plate 1. It is also possible to effectively reduce the bonding power of the adhesive portion 6 by providing a heater to a lower portion of the suction plate 13a.

According to the present invention described above, it is possible to release the support plate 1 with a plurality of through holes 3 and the wafer 5 from each other by pulling on the bottom surface of the support plate 1. Accordingly, stress applied to wafer 5 when releasing the support plate 1 and the wafer 5 from each other can be reduced.

The flat portions 4 are belt-shaped circles around the central portion 2a of the support plate 1, and accordingly θ alignment (rotary alignment) does not have to be performed between the support plate 1 and the carrier device 11 (holding means 15), making the process of releasing the support plate 1 and the wafer 5 easier.

Additionally, as there are a plurality (three in this example) of flat portions 4 on the support plate 1, the support plate 1 and the wafer 5 can be released from each other with the bottom surface 2 of the support plate 1 being pulled upon with an even force. Thereby, stress applied to the wafer when the support plate 1 with through holes 3 and the wafer 5 are released from each other can be reduced more effectively.

Also, with the width L of each flat portion 4 being between 0.3 mm and 0.2 mm, a release agent can be effectively injected via the through holes 3 while securing the width of each flat portion 4 in order to allow the holding by suction, etc. Thereby, stress applied to the wafer when the support plate 1 with through holes 3 and the wafer 5 are released from each other can be reduced more effectively.

Also with the width L1 of each flat portion 4 being at least 1.2 times a value obtained by subtracting the diameter D from the pitch P of the through holes 3, a release agent can be effectively injected via the through holes 3 while securing the width of each flat portion 4 in order to allow the holding by suction, etc. Thereby, stress applied to the wafer when the support plate 1 with through holes 3 and the wafer 5 are released from each other can be reduced more effectively.

Also, with the width L1 of each flat portion 4 being greater than the diameter D of each through hole 3, the width of each flat portion 4 can be effectively secured in order to allow the holding by suction, etc.

Also, with the diameter D and pitch P of each through hole 3 being between 0.3 mm and 0.5 mm and being between 0.5 mm and 1.0 mm respectively, a release agent can easily reach the adhesive portion 6 through the through holes 3, and accordingly the support plate 1 and the wafer 5 can effectively be released from each other with the bottom surface 2 of the support plate being pulled upon using the flat portions 4. Thereby, stress applied to the wafer when the support plate 1 with through holes 3 and the wafer 5 are released from each other can be reduced more effectively.

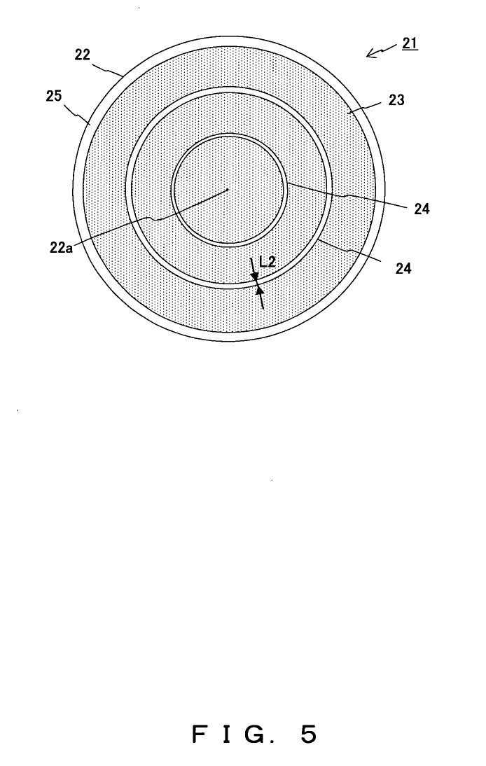

FIG. 5 is a plan view showing a support plate according to another embodiment.

A support plate 21 in FIG. 5 supports a wafer to be thinned through, for example, a grinding process. The support plate 21 supports, via a bonding portion made of an adhesive agent, tape, etc., the wafer on its supporting surface (not shown in FIG. 21) disposed on the surface opposite to a bottom surface 22 shown in FIG. 1.

A plurality of through holes 23 are formed through the support plate 21. The through holes 23 pierce the support plate 21 from the supporting surface to the bottom surface 22 (in the thickness direction). Two belt-shaped flat portions 24 on which the through holes 23 are not formed are formed on the bottom surface 22. The respective flat portions 24 are formed in such a manner that they form concentric circles around a central portion (central point) 22a of the bottom surface 22 in the present example.

In this configuration, the diameter of the support plate 21 is greater than that of a wafer to which the support plate 21 is to be adhered. The support plate 21 has an outer peripheral flat portion 25 along a portion that does not support wafers (peripheral portion). When the support plate 21 is to be held via suction using the holding means 15 shown in FIGS. 4A and 4B, the suction grooves 15a of the holding means 15 have to be provided with an ability to suction and hold the flat portions 24 on the support plate 21 shown in FIG. 5.

It is desirable that the width L2 of each flat portion 24 be between 0.3 mm and 2.0 mm. It is also desirable that the width L2 of each flat portion 24 be at least 1.2 times a value obtained by subtracting the diameter D from the pitch P of the through holes 23 shown in FIG. 2.

Further, it is desirable that the width L2 of each flat portion 24 be greater than the diameter D of each through hole 23. It is also desirable that the diameter D of each through hole 23 be between 0.3 mm and 0.5 mm and that the pitch P be between 0.5 mm and 1.0 mm.

However, as the above values of the width L2 of each flat portion 24 and the pitches P and diameters D of the through holes 23 are only preferable examples, they can be set appropriately on the basis of the size of the support plate 21 or the wafer, the property of a release agent supplied via the through holes 23, the material of an adhesive portion between the support plate 21 and the wafer, the size of a releasing device, etc.

According to the present embodiment, because the diameter of the support plate 21 is greater than that of the wafer and is provided with the outer peripheral flat portion 25 at the peripheral portion, the support plate and the wafer can be released from each other with the bottom surface 22 of the support plate 21 being pulled upon by using the flat portion 24 that is independent of the outer peripheral flat portion 25 not facing the wafer when they are adhered to each other. Accordingly, stress applied to wafers when the support plate 21 with the through holes 23 and a wafer are released from each other can be suppressed.

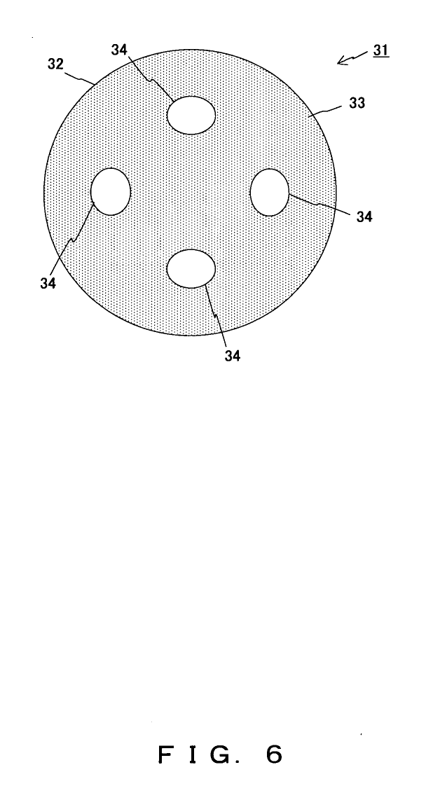

FIGS. 6 through 8 are plan views showing support plates according to other embodiments.

A plurality of through holes 33 are formed through a support plate 31 shown in FIG. 6. The through holes 33 pierce the support plate 31 from the supporting surface to a bottom surface 32 (in the thickness direction). On the bottom surface 32, four island-like elliptic flat portions 34 on which the through hole 33 is not formed are formed.

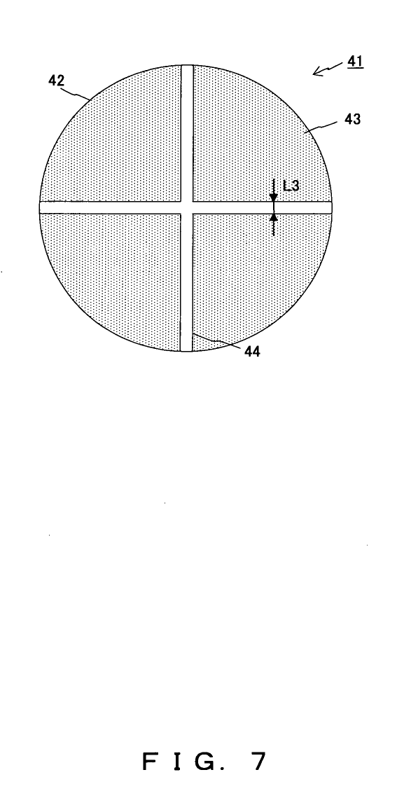

Also, through a support plate 41 shown in FIG. 7, a plurality of through holes 43 are formed. The through holes 43 pierce the support plate 41 from the supporting surface to a bottom surface 42 (in the thickness direction). On the bottom surface 42, a belt-like cross-shaped flat portion 44, on which the plurality of through holes are not formed, is formed. It is desirable that a value within ranges explained as ranges for the width L1 shown in FIG. 1 or the width L2 shown in FIG. 5 be employed as the value for the width L3 of the flat portion 44.

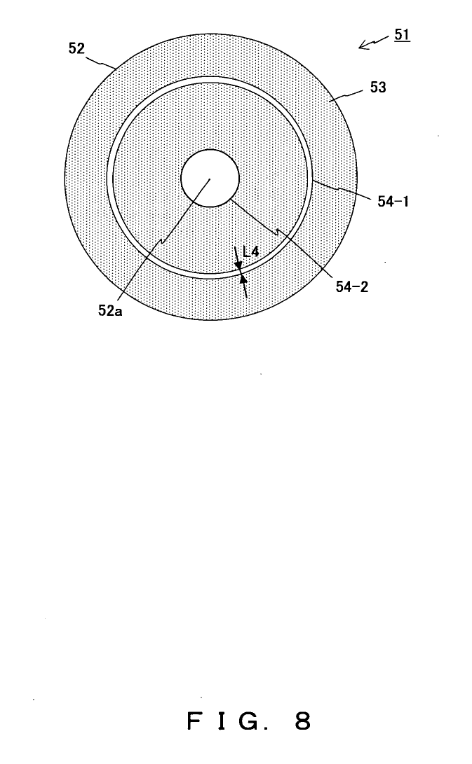

Also, through a support plate 51 shown in FIG. 8, a plurality of through holes 53 are formed. The through holes 53 pierce the support plate 51 from the supporting surface to a bottom surface 52 (in the thickness direction). On the bottom surface 52, a belt-shaped flat portion 54-1 and an island-like circular flat portion 54-2 around a central portion (central point) 52a are formed. On either the flat portion 54-1 or 54-2, the through hole 53 is not formed. It is desirable that a value within ranges explained as ranges for the width L1 shown in FIG. 1 and the width L2 shown in FIG. 5 be employed as the value for the width L4 of the flat portion 54.

By using any of the support plates 31, 41, and 51 respectively shown in FIGS. 6 through 8, a support plate and a wafer can be released from each other by suctioning and holding the flat portions on the support plate (i.e. with the bottom surface of the support plate being pulled upon) using, for example, holding means shown in FIGS. 4A and 4B. Accordingly, stress applied to a wafer when a support plate with through holes and a wafer are to be released from each other can be suppressed.

1. A support plate for supporting a wafer, comprising:
a plurality of through holes piercing the support plate in a thickness direction; and
a belt-shaped or island-like flat portion on which the plurality of through holes are not formed.

2. The support plate according to claim 1, wherein:
a diameter of the support plate is greater than that of the wafer; and
the support plate is further provided with an outer peripheral flat portion along a periphery of the support plate.

3. The support plate according to claim 2, wherein:
the flat portion is belt-shaped and circular around a central portion of the support plate.

4. The support plate according to claim 3, comprising:
a plurality of the flat portions.

5. The support plate according to claim 4, wherein:
the flat portion is belt-shaped and is between 0.3 mm and 2.0 mm in width.

6. The support plate according to claim 5, wherein:
the flat portion is belt-shaped and has a width at least 1.2 times a value obtained by subtracting a diameter of the through hole from a pitch of the through holes.

7. The support plate according to claim 6, wherein:
the flat portion is belt-shaped, and has a width greater than a diameter of the through hole.

8. The support plate according to claim 7, wherein:
the through hole is between 0.3 mm and 0.5 mm in diameter and between 0.5 mm and 1.0 mm in pitch.

9. A carrier device for carrying a support plate according to claim 1, comprising:
a holder to suction and hold the flat portion.

10. The carrier device according to claim 9, wherein:
the holder includes a suctioning groove corresponding to the flat portion, and suctions and holds the support plate via the suctioning groove.

11. A releasing device for releasing a support plate and a wafer adhered to each other, comprising:
the carrier device according to claim 9; and
release agent supplier to supply a release agent.

12. A method of releasing the support plate according to claim 1 and a wafer held on the support plate via an adhesive portion, comprising:
making a release agent reach the adhesive portion via the through holes in order to make the release agent dissolve the adhesive portion; and
releasing the support plate while suctioning and holding the flat portion.

13. The support plate according to claim 1, comprising a plurality of the flat portions.

14. The support plate according to claim 1, wherein the flat portion is belt-shaped and is between 0.3 mm and 2.0 mm in width.

15. The support plate according to claim 1, wherein the flat portion is belt-shaped and includes a width at least 1.2 times a value obtained by subtracting a diameter of the through hole from a pitch of the through holes.

16. The support plate according to claim 1, wherein the flat portion is belt-shaped and includes a width greater than a diameter of the through hole.

17. The support plate according to claim 1, wherein the through hole is between 0.3 mm and 0.5 mm in diameter and between 0.5 mm and 1.0 mm in pitch.
